(19) United States
(12) Patent Application Publication
(10) Pub. No.: US 2024/0365673 A1
(43) Pub. Date: Oct. 31, 2024

(54) TREATMENT OF SIDEWALL OF TUNNEL BARRIER JUNCTION

(71) Applicant: INTERNATIONAL BUSINESS MACHINES CORPORATION, ARMONK, NY (US)

(72) Inventors: Michael Rizzolo, Delmar, NY (US); Julien Frougier, Albany, NY (US); Hemanth Jagannathan, Niskayuna, NY (US)

(21) Appl. No.: 18/307,030

(22) Filed: Apr. 26, 2023

(51) Int. Cl. H10N 50/01; G11C 11/16; H10B 61/00; H10N 50/10; H10N 50/85

(52) U.S. Cl. CPC H10N 50/01; G11C 11/161; H10B 61/00; H10N 50/10; H10N 50/85

(57) ABSTRACT

Embodiments of present invention provide a method of forming a MRAM structure. The method includes providing a supporting structure, forming a free layer on top of the supporting structure, a tunnel barrier layer on top of the free layer, and a reference layer on top of the tunnel barrier layer; etching the reference layer, the tunnel barrier layer, and the free layer to form a magnetic tunnel junction (MTJ) stack on top of the supporting structure; the MTJ stack having sidewalls of the reference layer, the tunnel barrier layer, and the free layer being exposed; performing an in-situ oxidation of the sidewalls of the tunnel barrier layer; performing an in-situ etching of the sidewalls of the tunnel barrier layer with an anhydrous vapor-phase etch chemistry; and performing an in-situ encapsulation of the sidewalls of the tunnel barrier layer. A structure formed by the method is also provided.

### BACKGROUND

The present application relates to manufacturing of semiconductor integrated circuits. More particularly, it relates to a method of treating sidewalls of a tunnel barrier junction stack and devices that employ the tunnel barrier junction stack.

Magnetoresistive random-access-memory (MRAM), including spin-transfer-torque (STT) MRAM and spin-orbit-torque (SOT) MRAM, have been widely used in modern data storage devices. A MRAM device usually includes a tunnel barrier junction (MTJ) stack that includes a free layer, a tunnel barrier layer, and a reference layer. Other devices such as, for example, resistive random-access-memory (ReRAM) and phase-change-memory (PCM) may employ MTJ stack as well. In forming the MTJ stack, an etching process, such as a reactive-ion-etch (RIE) process or an ion beam etch (IBE) process, may be employed that, after the process, may inadvertently cause some metallic residues to remain on the sidewalls of the MTJ stack. Particularly, metallic residues at the sidewalls of the tunnel barrier layer may cause a short circuit across the tunnel barrier layer and thus resulting device failure.

In view of the above, the state-of-the-art MRAM technology often applying the IBE process, for example, in an extensive over-etching process to remove the sidewall residues, which consequently may induce gouging in the surrounding dielectric material, causing integration-related issues down the process. Moreover, certain tunnel barrier materials such as magnesium-oxide may not be compatible with many H₂O-containing wet cleaning process due to the fact that that tunnel barrier materials are hygroscopic.

### SUMMARY

Embodiments of present invention provide a method of forming a device. The method includes forming a stack of metal layers on top of a supporting structure, the stack of metal layers including a free layer, a reference layer, and a tunnel barrier layer between the free layer and the reference layer; etching the stack of metal layers to form one or more metal pillars, thereby creating sidewalls of the tunnel barrier layer, the free layer, and the reference layer; performing an in-situ oxidation of the sidewalls of the tunnel barrier layer; performing an in-situ etching of the sidewalls of the tunnel barrier layer with an anhydrous vapor-phase etch chemistry; and performing an in-situ encapsulation of the sidewalls of the tunnel barrier layer.

In one embodiment, etching the stack of metal layers causes one or more metallic residues being formed at the sidewalls of the tunnel barrier layer, where the in-situ oxidation oxidizes the one or more metallic residues to become one or more metal oxides.

In another embodiment, the in-situ etching removes the one or more metal oxides from the sidewalls of the tunnel barrier layer without exposing the tunnel barrier layer to moisture.

In yet another embodiment, the anhydrous vapor-phase etch chemistry used in the in-situ etching is either fluorine-based or chlorine-based.

In one embodiment, the one or more metal oxides are tantalum-oxide (TaO), titanium-oxide (TiO, and/or ruthenium-oxide (RuO).

In another embodiment, the in-situ etching causes the sidewalls of the tunnel barrier layer being etched more than the sidewalls of the free layer and the reference layer thereby creating a recess, wherein a width of the recess is less than 1 nm.

In yet another embodiment, the in-situ encapsulation creates an encapsulation layer, the encapsulation layer being a material of silicon-nitride (SIN), silicon-oxide (SiO), or aluminum-oxide (AlO) and filling the recess between the free layer and the reference layer.

In one embodiment, the encapsulation layer covers at least a portion of the sidewalls of the free layer and at least a portion of the sidewalls of the reference layer.

In another embodiment, the etching of the stack of metal layers and the in-situ etching creates a gouge in the supporting structure between a first and a second metal pillar of the one or more metal pillars, where a depth of the gouge is less than 10 nm.

In yet another embodiment, the tunnel barrier layer includes a magnesium-oxide (MgO) having a thickness around 2 nm.

Embodiments of preset invention further provide a device. The device includes one or more metal pillars on top of one or more conductive vias, the one or more conductive vias being embedded in a dielectric layer; and at least one of the one or more metal pillars includes a free layer, a tunnel barrier layer, and a reference layer, where a sidewall of the tunnel barrier layer is horizontally recessed with respect to sidewalls of the free layer and the reference layer, and a width of the recess is horizontally less than 1 nm.

### BRIEF DESCRIPTION OF THE DRAWINGS

The present invention will be understood and appreciated more fully from the following detailed description of embodiments of present invention, taken in conjunction with accompanying drawings of which:

FIGS. 1A, 1B, 1C, and 1D are demonstrative illustrations of cross-sectional views of a device at several steps of manufacturing thereof according to one embodiment of present invention;

FIG. 2 is a demonstrative illustration of a cross-sectional view of a device manufactured according to one embodiment of present invention;

FIG. 3 is a demonstrative illustration of a flow-chart of a method of manufacturing a device according to embodiments of present invention; and

FIG. 4 is a demonstrative illustration of a cross-sectional view of a device as is known in the art.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

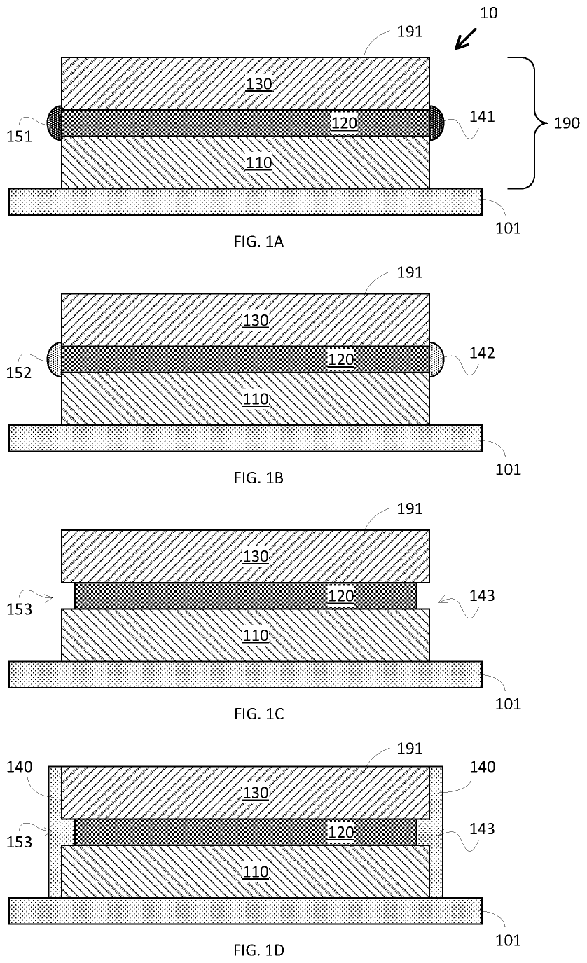

FIGS. 1A, 1B, 1C, and 1D are demonstrative illustrations of cross-sectional views of a device at several steps of manufacturing thereof according to one embodiment of present invention. For example, FIGS. 1A, 1B, 1C, and 1D may be demonstrative illustrations of cross-sectional views of a magnetoresistive random-access memory (MRAM) 10. For example, the MRAM 10 may be a spin-torque transfer (STT) MRAM or a spin-orbit-transfer (SOT) MRAM. However, embodiments of present invention are not limited in this aspect and the device may be any types of MRAM. In fact, the device illustrated in FIGS. 1A-1D may be a device other than a MRAM, such as a ReRAM, a PCM, or any device that employs a stack of metal layers that includes a tunnel barrier layer.

More particularly, embodiments of present invention provide receiving or providing a supporting structure 101 such as, for example, a dielectric layer and forming a stack of metal layers 190 on top of the supporting structure 101. The stack of metal layers 190 may include a top metal layer, a tunnel barrier layer, and a bottom metal layer with the tunnel barrier layer being sandwiched between the top metal layer and the bottom metal layer.

More particularly, in the non-limiting example of forming the MRAM 10, the stack of metal layers may include, for example, a first ferromagnetic layer 110 on top of the supporting structure 101; a tunnel barrier layer 120 on top of the first ferromagnetic layer 110; and a second ferromagnetic layer 130 on top of the tunnel barrier layer 120. As an example, the first and the second ferromagnetic layer 110 and 130 may be, independently, a layer of cobalt (Co), iron (Fe), and boron (B) based material (CoFeB) such as, for example, an alloy of Co, Fe, and B. The tunnel barrier layer 120 may be a layer of magnesium-oxide (MgO) or other suitable materials such as, for example, aluminum-oxide (Al₂O₃), titanium-oxide (TiO₂), hafnium-oxide (HfOₓ), or niobium-oxide (NbOₓ), to list a few.

The stack of metal layers 190 may be patterned to form one or more metal pillars, which may be known as magnetic tunnel junction (MTJ) stacks in the MRAM 10. For example, a MTJ stack 191 may be formed from the stack of metal layers 190 through, for example, a reactive-ion-etch (RIE) process or an ion-beam-etch (IBE) process. The RIE or IBE process may result in some conductive or metallic residues during the etching process, and after forming the MTJ stacks by the etching process, may cause one or more of these conductive or metallic residues to remain or be left on sidewalls of the MTJ stacks, in particular on sidewalls of the tunnel barrier layer. For example, as is demonstratively illustrated in FIG. 1A, conductive or metallic residues 141 and 151 may be caused to remain on the sidewalls of the tunnel barrier layer 120. The conductive or metallic residues 141 and 151, if not being properly removed, may cause short of the MTJ stack 191.

According to one embodiment of present invention, as is illustrated in FIG. 1B, an in-situ oxidation process may be applied to oxidize the metallic residues into metal oxides or nitride-oxides. For example, in one embodiment, the metallic residues may be metal elements such as, for example, tantalum (Ta), titanium (Ti), and/or ruthenium (Ru) or maybe substances that contain Ta, Ti, and/or Ru. The in-situ oxidation process may oxidize or transform the metallic residues 141 and 151 of metal element Ta, Ti, and/or Ru into metal oxides 142 and 152 of tantalum-oxide (TaO) or tantalum-nitride-oxide (TaNₓO_{y}), titanium-oxide (TiO), and/or ruthenium-oxide (RuO). An in-situ process, such as the in-situ oxidation process, may be a process where the device under processing (DUP) situates in the original place such as in a chamber while the oxidation process is being carried out. In other words, the DUP is not taken out the chamber, which could otherwise potentially expose the DUP to moisture when the process is changed from one to another.

As is illustrated in FIG. 1C, embodiments of present invention provide performing an in-situ etching of the sidewalls of the tunnel barrier layer 120, in particular in-situ etching of the metal oxides 142 and 152 formed from the metallic residues 141 and 151, with an anhydrous vapor-phase etch chemistry. The in-situ etching removes the one or more metal oxides 142 and 152 from the sidewalls of the tunnel barrier layer 120. In one embodiment, the anhydrous vapor-phase etch chemistry used in the in-situ etching may be similar to those used in the remote plasma assisted dry etch process that involves the simultaneous exposure of a DUP to H₂, NF₃ and NH₃ plasma by-products, such as in a SiConi™ etch process. More particularly, the anhydrous vapor-phase etch chemistry may be either fluorine-based or chlorine-based. The anhydrous nature of the chemistry, as well as the nature of in-situ etching, avoid the exposure of the tunnel barrier layer 120 to moisture thereby preventing damaging moisture ingress into the tunnel barrier layer 120.

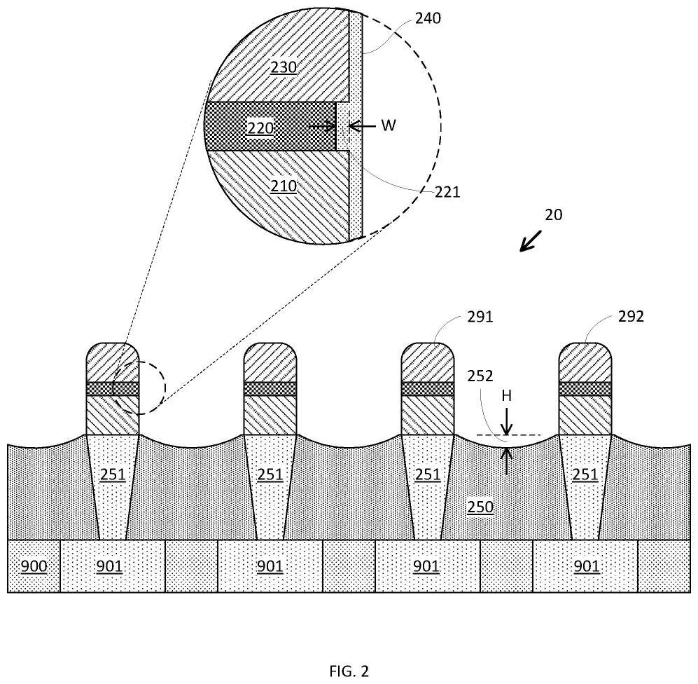

The in-situ etching process may be a selective etching process and may be selective to the metal oxides at the tunnel barrier layer 120, relative to the free layer 110 and the reference layer 130. Nevertheless, it may cause some etching of the tunnel barrier layer 120. In one instance, the in-situ etching may cause the sidewalls of the tunnel barrier layer 120 being etched, even though slightly, more than the sidewalls of the free layer 110 and the reference layer 130 thereby creating a shallow or small recess. For example, in one embodiment, the in-situ etching process may apply the anhydrous vapor-phase etch chemistry to remove the metal oxides 142 and 152, together with a portion of the tunnel barrier layer 120, thereby resulting in or creating recesses 143 and 153 at the sidewalls of the tunnel barrier layer 120 between the free layer 110 and the reference layer 130 as is illustrated in FIG. 1C. However, when being compared with the conventional approach of applying an IBE process to remove the metallic residues, the recesses 143 and 153 resulted from the etching process using the anhydrous vapor-phase etch chemistry are much shallower or smaller than those that otherwise would be created by the IBE process. Moreover, the etching process using the anhydrous vapor-phase etch chemistry creates less or almost no corner rounding of the free layer 110 and the reference layer 130 next to the tunnel barrier layer 120, as being described below in more details with reference to FIG. 2.

As is illustrated in FIG. 1D, embodiments of present invention provide performing an in-situ deposition process by forming an encapsulation layer 140 at the sidewalls of the tunnel barrier layer 120. The encapsulation layer 140 covers the recesses 143 and 153 that are between the free layer 110 and the reference layer 130 at the sidewalls of the tunnel barrier layer 120. In one embodiment, the encapsulation layer 140 may cover at least a portion of sidewalls of the free layer 110 and at least a portion of the sidewalls of the reference layer 130. The encapsulation layer 140 may be a layer of material such as, for example, silicon-nitride (SiN), silicon-oxide (SiO), or aluminum-oxide (AlO) and may protect the tunnel barrier layer 120 from oxidation or exposure to ambient moisture.

FIG. 2 is a demonstrative illustration of a cross-sectional view of a device manufactured according to one embodiment of present invention. More particularly, FIG. 2 illustrates a MRAM structure 20 having one or more MTJ stacks, such as MTJ stacks 291 and 292, formed on top of a supporting structure 250 such as a dielectric layer. The supporting structure 250 may be formed on top of a dielectric layer 900 which has one or more metal lines 901 embedded therein. One or more conductive vias 251 may be embedded in the supporting structure 250 and in contact with the one or more metal lines 901. The one or more MTJ stacks of the MRAM structure 20 may be formed on top of the one or more conductive vias 251.

As is illustrated in the expanded insert of FIG. 2, the MTJ stack (for example MTJ stack 291) may include a free layer 210, a tunnel barrier layer 220 on top of the free layer 210, and a reference layer 230 on top of the tunnel barrier layer 220. After removing the metal oxides (such as metal oxides 142 and 152 illustrated in FIG. 1B) at the sidewalls of the tunnel barrier layer 220 using an anhydrous vapor-phase etch chemistry, a resulting recess 221 at the sidewall of the tunnel barrier layer 220 may have a depth, shown here as a width W, that is about 1 nm or less and the recess 221 may be covered by a subsequently formed encapsulation layer 240.

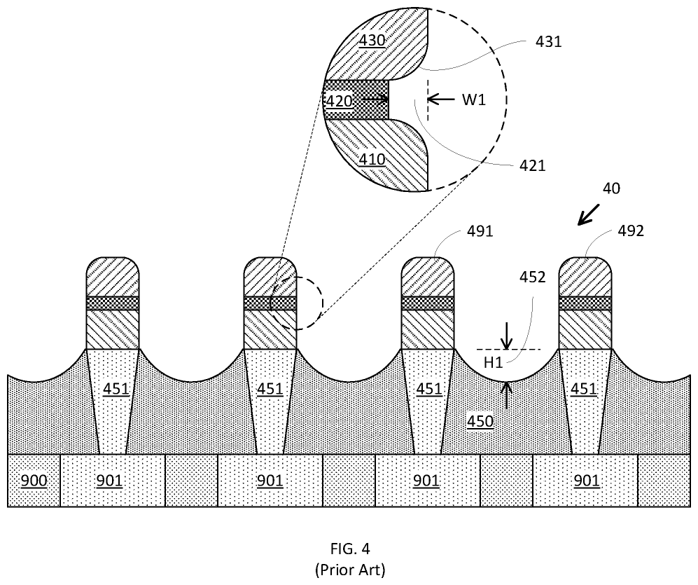

Because of the less aggressiveness nature of the anhydrous vapor-phase etch chemistry, as is compared with a traditional IBE based residue removing process, the resulting recess 221 is much shallower or smaller than a recess that may be caused by the traditional IBE based residue removing process. Reference is briefly made to FIG. 4, which is a demonstrative illustration of a cross-sectional view of a device as is known in the art. More particularly, FIG. 4 illustrates a MRAM structure 40 where the traditional IBE based process may be applied to remove any metallic residues at the sidewalls of tunnel barrier layer after patterning to form the MTJ stack. Multiple MTJ stacks such as MTJ stack 491 and MTJ stack 492 may situate on top of multiple conductive vias 451 that are electrically connected to multiple metal lines 901 in a dielectric layer 900. As is illustrated in FIG. 4, the IBE based residue removing process may cause a recess 421, at the sidewall of a tunnel barrier layer 420, with a width W1 that could be in the range of 2 nm to 4 nm, more than double or even quadruple the width W of the recess 221, which is typically 1 nm or less, resulting from the etching process using the anhydrous vapor-phase etch chemistry according to embodiments of present invention. Moreover, corners of a free layer 410 and a reference layer 430 next to the tunnel barrier layer 420 may be rounded up due to roughness of the aggressive IBE etching process such that, for example, it become a rounded corner 431.

Moreover, the IBE based residue removing process may also create deep gouges between neighboring MTJ stacks such as a gouge 452 between the MTJ stack 491 and the MTJ stack 492. The depth H1 of the gouge 452 may typically be between 15 nm to 30 nm, as compared with a much shallower or smaller gouge 252 as a result of etching using anhydrous vapor-phase etch chemistry, as is illustrated in FIG. 2.

Reference is made back to FIG. 2, where a shallower gouge 252 between MTJ stack 291 and MTJ stack 292 is illustrated. As a result of the less aggressive and selective etching process of using anhydrous vapor-phase etch chemistry, the gouge 252 typically has a depth H that is about 10 nm or less. This is critical important in the subsequent integration process because a less gouged supporting structure 250 such as dielectric layer may benefit downstream integration process in several ways. For example, a reduced gouge makes downstream dielectric planarization between the MTJ arrays and non-array regions of the wafer (i.e., logic-only or KERF regions) easier, requiring less CMP process. A reduced gouge also changes the angle of deposition for the dielectric when the dielectric fills spaces between the metal pillars or MTJ stacks, thereby reducing the risk of dielectric seam formation. Moreover, a reduced gouge allows for improved scaling by increasing the distance between the substrate level below the device and the depth at which the IBE process may reach. If IBE process etches too close to the underlying interconnect level, it may cause wiring shorts and/or degrades the dielectric cap performance for TDDB/electromigration.

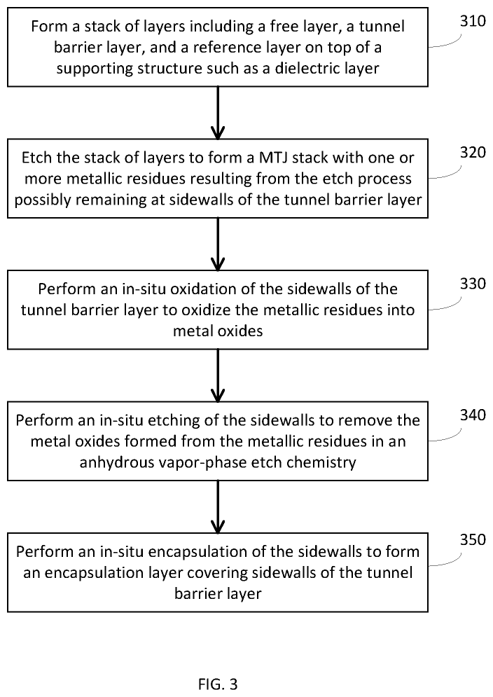

FIG. 3 is a demonstrative illustration of a flow-chart of a method of manufacturing a device such as a MRAM structure according to embodiments of present invention. The method includes (310) forming a stack of layers on top of a supporting structure, the stack of layers including a free layer, a tunnel barrier layer on top of the free layer, and a reference layer on top of the tunnel barrier layer; (320) etching the stack of layers to form one or more MTJ stacks, where one or more conductive or metallic residues resulting from the etching process may remain or be left at sidewalls of the MTJ stacks particularly at sidewalls of the tunnel barrier layer; (330) performing an in-situ oxidation process to oxidize the one or more metallic residues into one or more metal oxides; (340) performing an in-situ etching process of the metal oxides at the sidewalls of the tunnel barrier layer to remove the metal oxides formed from the metallic residues, where the etching is performed using an anhydrous vapor-phase etch chemistry; and (350) performing an in-situ encapsulation process of the sidewalls to form an encapsulation layer covering sidewalls of the tunnel barrier layer and filling possible recesses.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions above have been presented for the purposes of illustration of various embodiments of present invention and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A method comprising:
forming a stack of metal layers on top of a supporting structure, the stack of metal layers including a free layer, a reference layer, and a tunnel barrier layer between the free layer and the reference layer;
etching the stack of metal layers to form one or more metal pillars, thereby creating sidewalls of the tunnel barrier layer, the free layer, and the reference layer;
performing an in-situ oxidation of the sidewalls of the tunnel barrier layer;
performing an in-situ etching of the sidewalls of the tunnel barrier layer with an anhydrous vapor-phase etch chemistry; and
performing an in-situ encapsulation of the sidewalls of the tunnel barrier layer.

2. The method of claim 1, wherein etching the stack of metal layers causes one or more metallic residues being formed at the sidewalls of the tunnel barrier layer, wherein the in-situ oxidation oxidizes the one or more metallic residues to become one or more metal oxides.

3. The method of claim 2, wherein the in-situ etching removes the one or more metal oxides from the sidewalls of the tunnel barrier layer without exposing the tunnel barrier layer to moisture.

4. The method of claim 3, wherein the anhydrous vapor-phase etch chemistry used in the in-situ etching is fluorine-based or chlorine-based.

5. The method of claim 2, wherein the one or more metal oxides are tantalum-oxide (TaO), titanium-oxide (TiO), and/or ruthenium-oxide (RuO).

6. The method of claim 1, wherein the in-situ etching causes the sidewalls of the tunnel barrier layer being etched more than the sidewalls of the free layer and the reference layer thereby creating a recess, wherein a width of the recess is less than 1 nm.

7. The method of claim 6, wherein the in-situ encapsulation creates an encapsulation layer, the encapsulation layer being a material of silicon-nitride (SIN), silicon-oxide (SiO), or aluminum-oxide (AlO) and filling the recess between the free layer and the reference layer.

8. The method of claim 7, wherein the encapsulation layer covers at least a portion of the sidewalls of the free layer and at least a portion of the sidewalls of the reference layer.

9. The method of claim 1, wherein the etching of the stack of metal layers and the in-situ etching creates a gouge in the supporting structure between a first and a second metal pillar of the one or more metal pillars, where a depth of the gouge is less than 10 nm.

10. The method of claim 1, wherein the tunnel barrier layer comprises a magnesium-oxide (MgO) having a thickness around 2 nm.

11. A device comprising:
one or more metal pillars on top of one or more conductive vias, the one or more conductive vias being embedded in a dielectric layer; and at least one of the one or more metal pillars includes a free layer, a tunnel barrier layer, and a reference layer,
wherein a sidewall of the tunnel barrier layer is horizontally recessed with respect to sidewalls of the free layer and the reference layer, and a width of the recess is horizontally less than 1 nm.

12. The device of claim 11, wherein a top surface of the dielectric layer is gouged with respect to a top surface of the one or more conductive vias, and a depth of the gouge is less than 10 nm.

13. The device of claim 12, further comprising an encapsulation layer, the encapsulation layer covers the sidewalls of the tunnel barrier layer, and at least a portion of the sidewalls of the free layer and at least a portion of the reference layer.

14. The device of claim 13, wherein the encapsulation layer is made of silicon-nitride (SiN), silicon-oxide (SiO), or aluminum-oxide (AlO).

15. The device of claim 11, wherein the tunnel barrier layer is made of a magnesium-oxide (MgO) and has a thickness around 2 nm.

16. A method comprising:
providing a dielectric layer;
forming a free layer on top of the dielectric layer, a tunnel barrier layer on top of the free layer, and a reference layer on top of the tunnel barrier layer;
etching the reference layer, the tunnel barrier layer, and the free layer to form a magnetic tunnel junction (MTJ) stack on top of the dielectric layer; the MTJ stack having sidewalls of the reference layer, the tunnel barrier layer, and the free layer exposed;
performing an in-situ oxidation of the sidewalls of the tunnel barrier layer;
performing an in-situ etching of the sidewalls of the tunnel barrier layer with an anhydrous vapor-phase etch chemistry; and
performing an in-situ encapsulation of the sidewalls of the tunnel barrier layer.

17. The method of claim 16, wherein etching the reference layer, the tunnel barrier layer, and the free layer causes one or more metallic residues of tantalum-nitride being formed at the sidewalls of the tunnel barrier layer, wherein the in-situ oxidation oxidizes the one or more metallic residues of tantalum-nitride into one or more metal oxides of tantalum-oxide.

18. The method of claim 17, wherein the in-situ etching removes the one or more metal oxides of tantalum-oxide from the sidewalls of the tunnel barrier layer, and the anhydrous vapor-phase etch chemistry used in the in-situ etching is either fluorine-based or chlorine-based.

19. The method of claim 16, wherein the in-situ etching creates a recess at the sidewalls of the tunnel barrier layer, and wherein the in-situ encapsulation creates an encapsulation layer filling the recess between the free layer and the reference layer, the encapsulation layer being a material of silicon-nitride (SiN), silicon-oxide (SiO), or aluminum-oxide (AlO).

20. The method of claim 19, wherein the encapsulation layer covers at least a portion of the sidewalls of the free layer and at least a portion of the sidewalls of the reference layer.
